(19) United States
(12) Patent Application Publication
(10) Pub. No.: US 2012/0104614 A1
(43) Pub. Date: May 3, 2012

(54) SEMICONDUCTOR DEVICE MANUFACTURING METHOD AND SEMICONDUCTOR DEVICE

(75) Inventors: Nobuyuki IKARASHI, Kanagawa (JP); Motofumi SAITOH, Kanagawa (JP); Kouji MASUZAKI, Kanagawa (JP)

(73) Assignee: RENESAS ELECTRONICS CORPORATION, Kawasaki-shi (JP)

(21) Appl. No.: 13/278,914

(22) Filed: Oct. 21, 2011

(30) Foreign Application Priority Data
Oct. 27, 2010 (JP) 2010-241250

(51) Int. Cl. H01L 23/532; H01L 21/3205

(52) U.S. Cl. 257/754; 438/655; 257/E21.296; 257/E23.157

(57) ABSTRACT

A semiconductor device manufacturing method which prevents the resistance of a Ni silicide layer from increasing due to an additive element. First, a reaction control layer which contains a metallic element with an atomic number greater than Ni and does not contain Ni is formed over a silicon layer. Then, Ni is deposited over the reaction control layer and the silicon layer, reaction control layer and Ni are heat-treated to form a Ni silicide layer in the silicon layer. It is preferable that the reaction control layer be comprised of a metallic element with an atomic number greater than Ni.

### CROSS-REFERENCE TO RELATED APPLICATIONS

The disclosure of Japanese Patent Application No. 2010-241250 filed on Oct. 27, 2010 including the specification, drawings and abstract is incorporated herein by reference in its entirety.

### BACKGROUND

The present invention relates to semiconductor devices having Ni silicide and semiconductor device manufacturing methods.

In a semiconductor device, a silicide layer is provided in a silicon layer in order to decrease the resistance. In recent years, studies on the use of Ni silicide for the silicide layer have been carried out. For the silicide layer used in a semiconductor device, NiSi is more suitable than NiSi₂.

Japanese Unexamined Patent Publication No. 2005-19943 describes a technique that a Ni silicide layer is formed by forming a Ni alloy film over a semiconductor substrate containing silicon and carrying out heat treatment.

Japanese Unexamined Patent Publication No. 2007-142347 describes a technique that a Ni silicide layer is formed by forming a Ni alloy film and a Ni film over a semiconductor substrate in the order of mention and carrying out heat treatment.

Japanese Unexamined Patent Publication No. 2009-260004 describes a technique that a Ni film or Ni alloy film is formed over a semiconductor substrate and a first heat treatment is carried out to form a metal silicide layer and further a second heat treatment at a higher temperature than the first heat treatment is carried out.

### SUMMARY

In the formation of a Ni silicide layer, Ni alloy is used in order to suppress the formation of NiSi₂. However, in this method, a considerable amount of metal must be added to Ni, so the Ni silicide layer has a high resistance.

According to one aspect of the present invention, there is provided a semiconductor device manufacturing method which includes forming over a silicon layer a reaction control layer containing a metallic element with an atomic number greater than Ni and not containing Ni, and forming a Ni silicide layer in the silicon layer by depositing Ni over the reaction control layer and heat-treating the silicon layer, the reaction control layer, and the Ni.

From the research made by the present inventors it has been found that the mechanism in which NiSi₂ is formed during the formation of a Ni silicide layer is as follows. If a Ni-adamantane structure is formed in Ni, NiSi₂ is easily formed. On the other hand, as the compression stress which Ni-adamantane receives from the silicon layer increases, it becomes harder to form a Ni-adamantane structure in Ni because the Ni-adamantane structure becomes unstable. Therefore, the important thing to prevent the formation of NiSi₂ is to increase the compression stress which Ni-adamantane receives from the silicon layer.

When a reaction control layer comprised of a metallic element with an atomic number greater than Ni is formed between the silicon layer and Ni as in the present invention, it decreases the compression stress which Ni receives from the silicon layer. Consequently, according to the present invention, the formation of NiSi₂ is suppressed in the formation of the Ni silicide layer. In addition, the reaction control layer is thin, which means that the required amount of the additive element contained in the Ni silicide layer being formed is small. This reduces the possibility of the Ni silicide layer having a high resistance due to the additive element.

According to another aspect of the present invention, there is provided a semiconductor device which includes a silicon layer and a Ni silicide layer formed at least in part of the silicon layer. The Ni silicide layer contains a metallic element with an atomic number greater than Ni and the concentration of the metallic element is the highest in the surface layer of the Ni silicide layer and lower in deeper regions.

According to the aspects of the present invention, the Ni silicide layer is prevented from having a high resistance due to an additive element.

### BRIEF DESCRIPTION OF THE DRAWINGS

FIGS. 1A to 1C are sectional views showing a semiconductor device manufacturing method according to a first embodiment of the invention;

FIGS. 2A and 2B are cross-sectional TEM images explaining the effect of the first embodiment, in which FIG. 2A shows a silicon layer in a semiconductor device manufacturing method according to a comparative example and FIG. 2B shows a silicon layer in the semiconductor device manufacturing method according to the first embodiment;

FIGS. 3A and 3B are sectional views showing a semiconductor device manufacturing method according to a second embodiment, in which FIG. 3A shows the formation of a reaction control layer and FIG. 3B shows the formation of a Ni silicide layer;

FIGS. 4A to 4C are sectional views showing a semiconductor device manufacturing method according to a third embodiment of the invention, in which FIG. 4A shows the formation of a Ni silicide layer, FIG. 4B shows the formation of a second Ni layer, and FIG. 4C shows the thickened Ni silicide layer; and

FIG. 5 is a sectional view showing a semiconductor device according to a fourth embodiment of the invention.

### DETAILED DESCRIPTION

Next, the preferred embodiments of the present invention will be described referring to the accompanying drawings. In all the drawings, like elements with like functions are designated by like reference numerals and their repeated description is omitted.

### First Embodiment

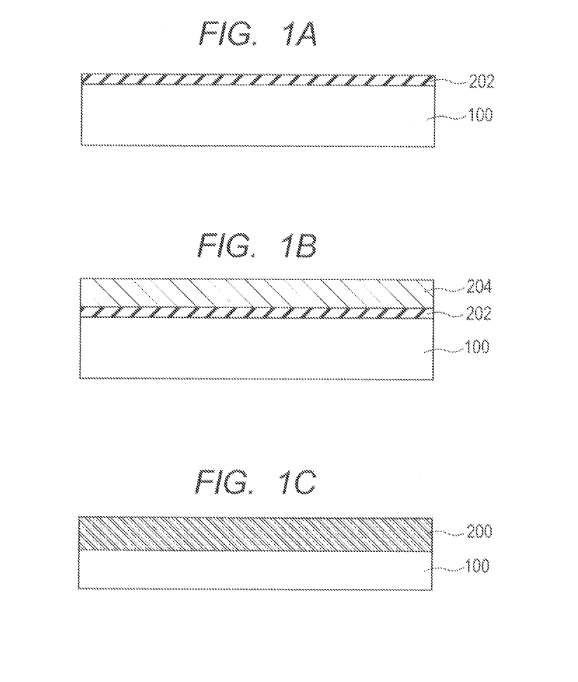

FIGS. 1A to 1C are sectional views showing a semiconductor device manufacturing method according to the first embodiment. The semiconductor device manufacturing method according to the first embodiment includes the following steps. First, a reaction control layer 202 which contains a metallic element with an atomic number greater than Ni and does not contain Ni is formed over a silicon layer 100. Then, Ni is deposited over the reaction control layer 202 and the silicon layer 100, reaction control layer 202 and Ni are heat-treated to form a Ni silicide layer 200 in the silicon layer 100. It is preferable that the reaction control layer 202 be comprised of a metallic element with an atomic number than Ni. These steps are described in detail below.

First, as shown in FIG. 1A, a reaction control layer 202 is formed over a silicon layer 100. The silicon layer 100 may be the surface layer of a silicon substrate, the silicon layer of an SOI substrate, or a silicon film formed on a substrate. The reaction control layer 202 contains not less than 50% metallic element with an atomic number greater than Ni. It is preferable that the reaction control layer 202 be only comprised of the above metallic element. More specifically, it is preferable that the metallic element be a metallic element whose ion radius is larger than that of Ni. The metallic element which can be used for the reaction control layer 202 is at least one among Pt, Ta, W, Hf, Zr, and Pd.

The reaction control layer 202 is formed, for example, by the atomic layer deposition (ALD) process. In order to decrease the resistance of the Ni silicide layer 200, it is desirable that the reaction control layer 202 be thin. The film thickness of the reaction control layer 202 is, for example, 0.3 nm or less. Also, the film thickness of the reaction control layer 202 is, for example, one atomic layer or less and the metallic element which constitutes the reaction control layer 202 covers more than half of the silicon layer 100 in which the Ni silicide layer 200 is formed.

Next, as shown in FIG. 1B, a first Ni layer 204 is formed over the reaction control layer 202. The first Ni layer 204 is formed, for example, by sputtering. It is preferable that the thickness of the first Ni layer 204 be 0.5 nm or more and 40 nm or less and more particularly 10 nm or less. If the thickness of the first Ni layer 204 should be less than 0.5 nm, it would be difficult to make the thickness of the first Ni layer 204 uniform. If the thickness of the first Ni layer 204 should be more than 40 nm, the reaction control layer 202 would be less effective. In this embodiment, in the process of forming the first Ni layer 204, the silicon layer 100 and reaction control layer 202 are kept at less than 300° C. This prevents silicide formation during the formation of the first Ni layer 204.

Next, as shown in FIG. 1C, the silicon layer 100, reaction control layer 202 and first Ni layer 204 are heated to 300° C. or more. Preferably the heating temperature is 500° C. or less, more preferably 450° C. or less. As a consequence, the first Ni layer 204 diffuses into the silicon layer 100 through the reaction control layer 202 and reacts to form a Ni silicide layer 200. For example, the average thickness of the Ni silicide layer 200 is 20 nm or less. At this time, the reaction control layer 202 is included in the Ni silicide layer 200 and the concentration of the metallic element constituting the reaction control layer 202 is the highest on the surface of the Ni silicide layer 200 or in the region from the surface to five atomic layers below the surface and the concentration is lower in deeper regions.

Next, the effect of the first embodiment will be described. As a result of the research made by the present inventors, the following finding has been reached. If a Ni-adamantane structure is formed in Ni, NiSi₂ is easily formed. On the other hand, as the compression stress which Ni receives from the silicon layer increases, it becomes harder to form a Ni-adamantane structure because the Ni-adamantane structure becomes unstable. Therefore, the important thing to prevent the formation of NiSi₂ is to decrease the compression stress which Ni receives from the silicon layer.

In this embodiment, the reaction control layer 202 exists between the silicon layer 100 and the first Ni layer 204. The reaction control layer 202 is comprised of a metallic element with an atomic number greater than Ni. Therefore, the existence of the reaction control layer 202 decreases the compression stress which Ni receives from the silicon layer. Consequently the formation of NiSi₂ is suppressed in the process of forming the Ni silicide layer 200. In addition, the reaction control layer 202 is thin, which means that the required amount of the additive element contained in the Ni silicide layer 200 is small. This reduces the possibility of the Ni silicide layer 200 having a high resistance due to the additive element. Furthermore, since the required amount of additive element is small, the rise in the manufacturing cost attributable to the additive element is suppressed.

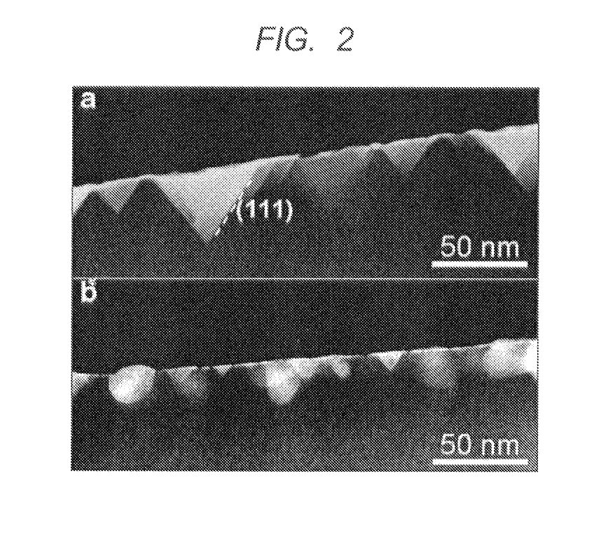

FIG. 2B is a cross-sectional TEM image of the silicon layer in which silicide is formed by the semiconductor device manufacturing method according to the first embodiment. FIG. 2A is a cross-sectional TEM image of the silicon layer in which silicide is formed by a semiconductor device manufacturing method according to a comparative example. The semiconductor device manufacturing method according to the comparative example is the same as the semiconductor device manufacturing method according to the first embodiment except that the reaction control layer 202 is not formed. In these cross-sectional TEM images, whitish spots represent Ni silicide.

As shown in FIG. 2A, in the semiconductor device manufacturing method according to the comparative example, the Ni silicide layer extends deep along the silicon (111) face in a spike pattern. This is because NiSi₂ is formed as the Ni silicide layer. On the other hand, as shown in FIG. 2B, in the semiconductor device manufacturing method according to the first embodiment, the Ni silicide layer is restricted from extending deep. This is because NiSi is formed as the Ni silicide layer instead of NiSi₂. When the Ni silicide layer is restricted from extending deep, for example, it is possible to make the source/drain region of a transistor smaller and shallower.

### Second Embodiment

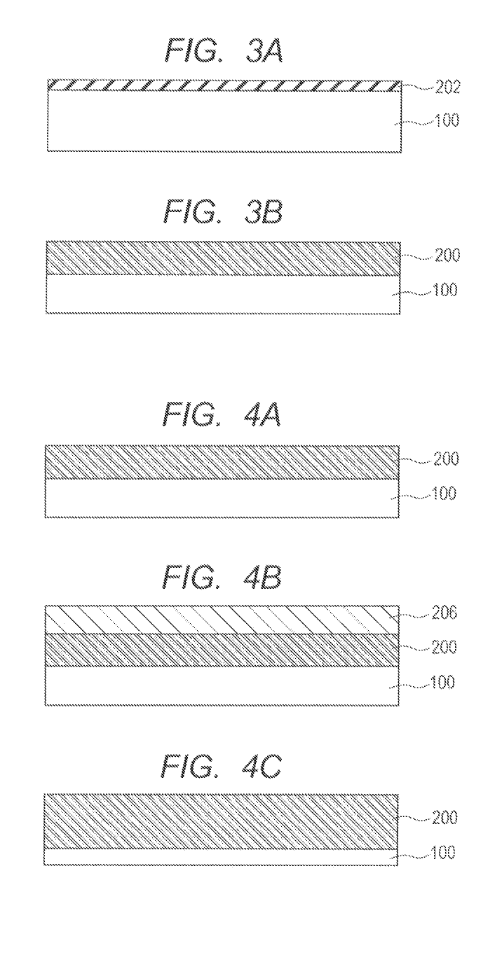

FIGS. 3A and 3B are sectional views showing a semiconductor device manufacturing method according to the second embodiment. First, a reaction control layer 202 is formed over a silicon layer 100 as shown in FIG. 3A.

Then, as shown in FIG. 3B, the silicon layer 100 and the reaction control layer 202 are heated to 300° C. or more so that Ni is deposited over the reaction control layer 202. Since the silicon layer 100 and reaction control layer 202 have a temperature of 300° C. or more, the Ni deposited over the reaction control layer 202 diffuses into the silicon layer 100, forming a Ni silicide layer 200. In this process, it is desirable that the temperatures of the silicon layer 100 and reaction control layer 200 be not more than 500° C. or more desirably not more than 450° C.

The second embodiment also brings about the same effect as the first embodiment. Since the Ni silicide layer 200 is formed simultaneously with the deposition of Ni, the number of semiconductor device manufacturing steps is decreased.

### Third Embodiment

FIGS. 4A to 4C are sectional views showing a semiconductor device manufacturing method according to the third embodiment. First, as shown in FIG. 4A, a Ni silicide layer 200 is formed over a silicon layer 100. The method for forming the Ni silicide layer 200 is the same as in the first embodiment or second embodiment.

Next, as shown in FIG. 4B, a second Ni layer 206 is formed over the Ni silicide layer 200. The second Ni layer 206 is formed, for example, by sputtering. It is preferable that the thickness of the second Ni layer 206 be not less than 0.5 nm or more and not more than 10 nm.

Next, as shown in FIG. 4C, the silicon layer 100, Ni silicide layer 200, and second Ni layer 206 are heat-treated. Preferably the heat treatment temperature is not less than 300° C. and not more than 500° C. As a consequence, the second Ni layer 206 also diffuses toward the silicon layer 100, so the Ni silicide layer 200 becomes thicker.

The third embodiment also bring about the same effect as the first or second embodiment. In addition, the Ni silicide layer 200 is thickened.

### Fourth Embodiment

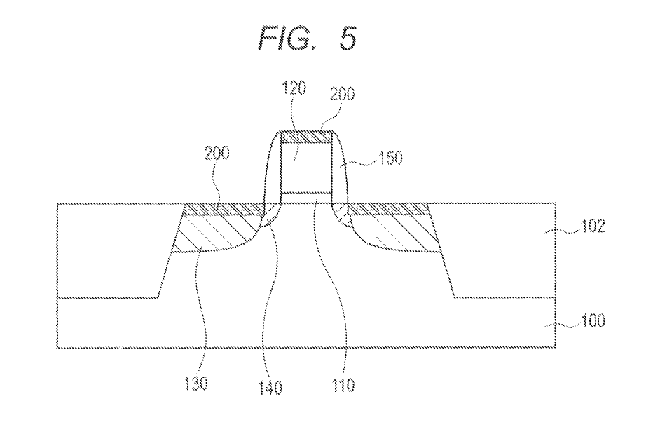

FIG. 5 is a sectional view showing a semiconductor device according to the fourth embodiment. In this embodiment, the Ni silicide layer 200 is formed over the surface layer of the source/drain region 130 of a MOS transistor and at least on the surface layer of the gate electrode 120. The method for forming the Ni silicide layer 200 is the same as in one of the first to third embodiments.

More specifically, the silicon layer 100 is a silicon substrate. An isolation membrane 102 is buried in the silicon substrate to isolate the device region for the formation of the MOS transistor from the other regions. A gate insulating film 110 and the gate electrode 120 are formed over part of the device region. The gate insulating film 110 may be a silicon oxide film or may include a film with a higher dielectric constant than silicon oxide. If the gate insulating film 110 is a silicon oxide film, the gate electrode 120 is a polysilicon film. If the gate insulating film 110 includes a film with a higher dielectric constant than silicon oxide, the gate electrode 120 is a laminate in which a metal gate (for example, a metal nitride film such as TiN) and a polysilicon film are stacked in the order of mention. A Ni silicide layer 200 is formed over the surface layer of the gate electrode 120 and a sidewall 150 is formed on the lateral side of the gate electrode 120.

A source/drain region 130 is formed in the silicon layer 100 on both sides of the gate electrode 120. The source/drain region 130, which is formed by doping the silicon layer 100 with impurities, has an extension region 140. The extension region 140 is located under the sidewall 150. The Ni silicide layer 200 is formed over the surface layer of the source/drain region 130. The average thickness of the Ni silicide layer 200 lying over the surface layer of the source/drain region 130 is 20 nm or less, preferably 10 nm or less.

The fourth embodiment also brings about the same effect as anyone of the first to third embodiments. Furthermore, the Ni silicide layer 200 lying over the surface layer of the source/drain region 130 is prevented from growing in a spike pattern. Therefore, even if the source/drain region 130 is shallow, the Ni silicide layer 200 is prevented from penetrating the source/drain region 130.

The preferred embodiments of the present invention have been described so far referring to the drawings, but they are just illustrative and the invention is not limited thereto. The invention may be embodied in other various ways.

What is claimed is:

1. A semiconductor device manufacturing method comprising:
forming over a silicon layer a reaction control layer containing a metallic element with an atomic number greater than Ni and not containing Ni; and
forming a Ni silicide layer in the silicon layer by depositing Ni over the reaction control layer and heat-treating the silicon layer, the reaction control layer, and the Ni.

2. The semiconductor device manufacturing method according to claim 1, wherein the metallic element has an ion radius larger than an ion radius of Ni.

3. The semiconductor device manufacturing method according to claim 1, wherein the metallic element is at least one among Pt, Ta, W, Hf, Zr, and Pd.

4. The semiconductor device manufacturing method according to claim 1, wherein the reaction control layer has a thickness of 0.3 nm or less.

5. The semiconductor device manufacturing method according to claim 1, wherein the reaction control layer has a film thickness of one atomic layer or less and the metallic element covers more than half of the silicon layer in which the Ni silicide layer is formed.

6. The semiconductor device manufacturing method according to claim 1, wherein the Ni silicide layer is formed in a surface layer of a source or drain of a transistor.

7. The semiconductor device manufacturing method according to claim 1, wherein in the step of forming a Ni silicide layer in the silicon layer, the Ni silicide layer is formed by heating the silicon layer at a temperature not less than 300° C. and not more than 500° C. to deposit Ni over the reaction control layer.

8. The semiconductor device manufacturing method according to claim 1, wherein the step of forming a Ni silicide layer in the silicon layer includes:
forming a first Ni layer over the reaction control layer with the silicon layer kept at less than 300° C.; and
forming the Ni silicide layer by heating the silicon layer, the reaction control layer, and the first Ni layer to 300° C. or more.

9. The semiconductor device manufacturing method according to claim 8, wherein the first Ni layer has a thickness of 40 nm or less.

10. The semiconductor device manufacturing method according to claim 7, further comprising:
forming a second Ni layer over the Ni silicide layer; and
thickening the Ni silicide layer by heat-treating the silicon layer, the Ni silicide layer, and the second Ni layer.

11. A semiconductor device comprising:
a silicon layer; and
a Ni silicide layer formed at least in part of the silicon layer,
wherein the Ni silicide layer contains a metallic element with an atomic number greater than Ni; and
wherein a concentration of the metallic element is the highest in a surface of the Ni silicide layer and lower in deeper regions.

12. The semiconductor device according to claim 11, wherein the metallic element has an ion radius larger than an ion radius of Ni.

13. The semiconductor device according to claim 11, wherein the metallic element is at least one among Pt, Ta, W, Hf, Zr, and Pd.

14. The semiconductor device according to claim 11, wherein the Ni silicide layer is formed in a surface layer of a source or drain of a transistor.

15. The semiconductor device according to claim 11, wherein the silicon layer is a silicon substrate surface layer.

16. The semiconductor device according to claim 11, wherein the Ni silicide layer has a thickness of 20 nm or less.
